(19) United States
(12) Patent Application Publication
(10) Pub. No.: US 2014/0251583 A1
(43) Pub. Date: Sep. 11, 2014

(54) LEAK DETECTION SYSTEM FOR A LIQUID COOLING SYSTEM

(71) Applicant: ASETEK A/S, Bronderslev (DK)

(72) Inventor: Andre Sloth Eriksen, Morgan Hill, CA (US)

(73) Assignee: Asetek A/S, Bronderslev (DK)

(21) Appl. No.: 13/788,938

(22) Filed: Mar. 7, 2013

(51) Int. Cl. H05K 7/20; G06F 1/20; F28F 1/00

(52) U.S. Cl. CPC H05K 7/20763; F28F 1/00; G06F 1/206
USPC 165/104.33

(57) ABSTRACT

A liquid cooling system for a computer may include a cold plate configured to be positioned on a heat generating electronic device of the computer and adapted to pass a coolant therethrough. The cooling system may also include a leak detection system configured to detect a coolant leak in the computer, and a control system coupled to the leak detection system. The control system may be configured to take remedial action when the coolant leak is detected by the leak detection system.

### TECHNICAL FIELD

The present invention is related to a leak detection system for a liquid cooling system, and liquid cooling systems that incorporate the leak detection system.

### BACKGROUND

Computers, and other electronic systems, include integrated circuit (IC) devices that generate heat during operation. For effective operation of the computer, the temperature of these IC devices has to be maintained below acceptable limits. While the problem of heat removal from IC devices is an old one, this problem has increased in recent years due to greater numbers of transistors that are packed into an IC device while reducing the physical size of the device. Increasing number of transistors compacted into a smaller area results in a greater concentration of heat that must be removed from that smaller area. Bundling multiple computer systems together, such as, for example, in a computer server, further aggravates the heat removal problem by increasing the amount of heat that has to be removed from a relatively small area.

U.S. application Ser. No. 13/215,384, filed Aug. 23, 2011, titled “Liquid Cooling System for a Server” discloses an exemplary liquid cooling system that may be used to effectively cool multiple nodes of a computer server. In the cooling system of the '384 application, a liquid coolant is circulated through the multiple nodes to cool the heat producing components of the server. One of the major concerns of applying liquid cooling systems to a computer is the possibility of coolant leaks occurring within the computer. While coolant leaks may be minimized with proper design of the cooling system, it may be impractical to design a totally leak proof system. The current disclosure is directed to addressing these and other limitations of existing liquid cooling systems.

### SUMMARY OF THE DISCLOSURE

In one aspect, a liquid cooling system for a computer is disclosed. The cooling system may include a cold plate configured to be positioned on a heat generating electronic device of the computer. The cold plate may be adapted to pass a coolant therethrough. The cooling system may also include a leak detection system configured to detect a coolant leak in the computer, and a control system coupled to the leak detection system. The control system may be configured to take remedial action when the coolant leak is detected by the leak detection system.

In another aspect, a liquid cooling system for a computer server is disclosed. The computer server may include multiple nodes arranged on a rack. The cooling system may include a first liquid loop configured to pass a coolant through a first node of the multiple nodes, and a second liquid loop configured to pass the coolant through a second node of the multiple nodes. The cooling system may also include a leak detection system configured to detect a coolant leak in the server, and a control system operatively coupled to the leak detection system and the first and second liquid loops. The control system may be configured to identify a node of the server in which the coolant leak occurred.

In yet another aspect, a liquid cooling system for a server room is disclosed. The server room may include multiple computer servers and each of the multiple servers may include multiple nodes arranged on a rack. The cooling system may include a liquid loop configured to pass a coolant through a plurality of nodes of the multiple computer servers to cool one or more electronic devices positioned in the plurality of nodes. The cooling system may also include a leak detection system configured to detect a coolant leak in the plurality of nodes, and a control system operatively coupled to the leak detection system and the liquid loop. The control system may be configured to identify a node of the plurality of nodes in which the coolant leak occurred.

### BRIEF DESCRIPTION OF THE DRAWINGS

FIG. 1 illustrates an exemplary server room housing multiple computer servers.

FIG. 2 illustrates multiple nodes of an exemplary server of FIG. 1.

FIG. 3 illustrates a node of the server of FIG. 2 being cooled by an exemplary liquid cooling system.

FIG. 4 is a schematic illustration of the multiple nodes of the server of FIG. 2 being cooled by an exemplary liquid cooling system.

FIG. 5A is a schematic cross-sectional illustration of an exemplary liquid cooling system with one embodiment of a leak detection system.

FIG. 5B is a top view of the leak detection system of FIG. 5A.

FIG. 6A is a schematic illustration of an exemplary liquid cooling system with a second embodiment of a leak detection system.

FIG. 6B is a schematic illustration of an exemplary liquid cooling system with a third embodiment of a leak detection system.

FIG. 7 is a schematic illustration of an exemplary liquid cooling system with a fourth embodiment of a leak detection system.

### DETAILED DESCRIPTION

The following detailed description illustrates the cooling system by way of example and not by way of limitation. Although the description below describes an application of the disclosed liquid cooling system to computer servers housed in a server room, embodiments of the disclosed cooling systems may be applied to cool heat generating components in any application. For example, embodiments of the current disclosure may be used to cool desktop computers, portable computers, or any other electronic system. The description enables one skilled in the art to make and use the present disclosure for cooling any electronic component within a console or a chassis.

Reference will now be made to exemplary embodiments of the invention, examples of which are illustrated in the accompanying drawings. Wherever possible, the same reference numbers will be used throughout the drawings to refer to the same or like parts. Elements designated using the same reference numbers in different figures perform similar functions. Therefore, for the sake of brevity, these elements may not be described with reference to every figure. In the description that follows, if an element is not described with reference to a figure, the description of the element made with reference to another figure applies.

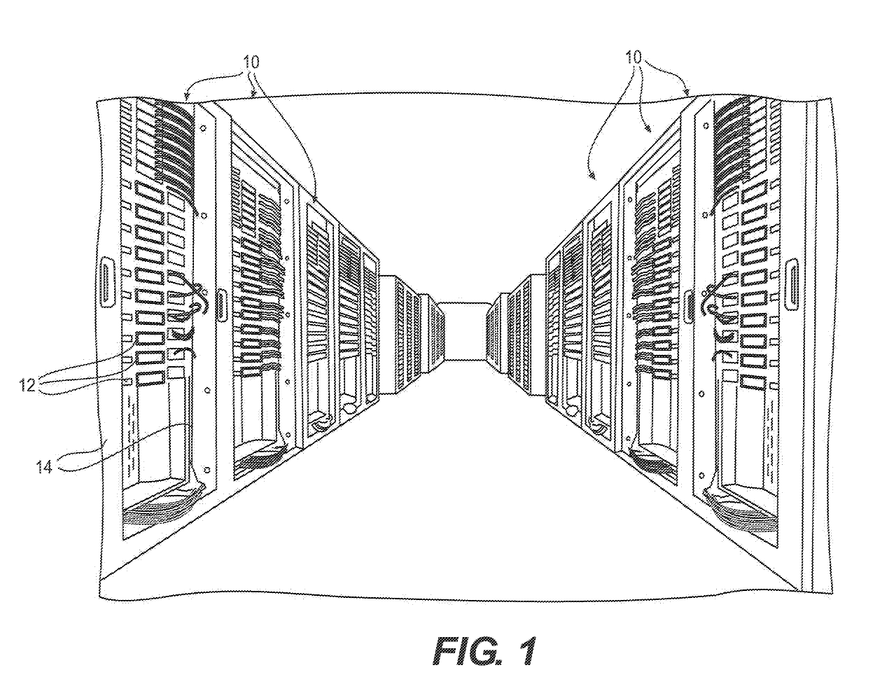

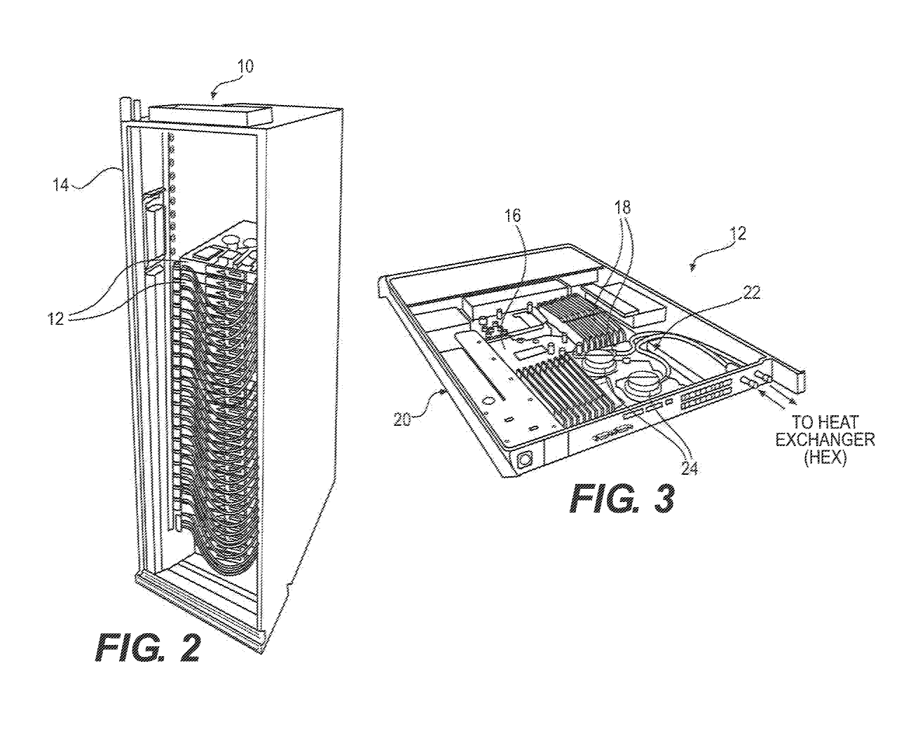

FIG. 1 illustrates an exemplary server room housing multiple computer servers 10. As illustrated in FIG. 2, each server 10 includes several modules or nodes 12 stacked together in a rack 14 or a case to consolidate network resources and minimize floor space. As is known in the art, each node 12 of server 10 may function as a separate computational unit, and may be similar or different from other nodes. Generally, as illustrated in FIG. 3, each node 12 is characterized by a motherboard 16 comprising heat generating electronic devices 18 (such as IC devices) housed in a modular case or chassis 20. Node 12 is mounted together with other similar nodes in the rack 14 to form server 10. The electronic devices 18 of node 12 may include, without limitation, any type of devices found in typical computer systems (such as, for example, CPUs, GPUs, memory, power supplies, disk drives, controllers, etc.) that generate heat.

Node 12 may also include a liquid cooling system 22 to cool one or more of the heat generating electronic devices 18. Liquid cooling system 22 may include one or more cold plates 24 placed in thermal contact (directly in contact, or in contact through a heat transfer medium, such as, for example, thermal grease or a thermal pad) with one or more of electronic devices 18 to cool these devices. Because of thermal contact, heat may be transferred from the electronic device 18 to the cold plate 24. A coolant of the liquid cooling system 22 may pass through the cold plate 24 to remove heat from, and thereby cool, the cold plate 24. Any type of apparatus configured to transfer heat from an electronic device 18 to a circulating coolant may be used as the cold plate 24. The cold plate 24 may include fins, pins, or other such features to assist in transferring the heat from the cold plate 24 to the coolant. In some embodiments, devices used to transfer heat from heat generating electronic devices to the coolant described in co-assigned U.S. Pat. Nos. 7,971,632, 8,240,362, 8,245,764, 8,274,787, 8,358,505, and U.S. patent application Ser. Nos. 11/919,974, 12/914,263, and 13/593,157 with appropriate modifications, may be used as the cold plate 24. These patent applications are incorporated by reference herein in their entirety. Although FIG. 3 illustrates two similar cold plates 24, in general, liquid cooling system 22 may include any number and type of cold plates 24.

The coolant may dissipate the heat from the cold plates 24 to another medium (such as, air or another liquid) at a heat exchanger (not shown). The relatively cooler coolant may then be circulated back to the cold plates 24 to absorb more heat and continue the cycle. The liquid cooling system 22 may include one or more pumps or other circulation devices (not shown) to circulate the coolant between the cold plates 24 and the heat exchanger. In some embodiments, the pump and control circuits that controls the operation (for example, speed, etc.) of the pump may be integrated with the cold plates 24 (see, for example, some of the cold plates described in U.S. Pat. Nos. 8,240,362 and 8,245,764). In some embodiments, the pump may be provided separate from the cold plates 24 (see for example, the cold plates described in U.S. Pat. Nos. 8,274,787 and 8,358,505). It is also contemplated that, some configurations of the liquid cooling system 22 may not include a pump. In such embodiments, the liquid cooling system 22 may instead rely upon the expansion and contraction of the coolant as it absorbs and dissipates heat to propel the coolant between the heat exchanger and the cold plates 24.

Any liquid, such as, for example, water, alcohol, mixtures of alcohol and water, etc. may be used as the coolant in liquid cooling system 22. In some embodiments, the coolant may also include an additive adapted to produce a desired characteristic (such as, smell, color, etc.) in coolant. Although the coolant is described as a liquid, in some embodiments, a phase change material may be used as the coolant. In these embodiments, a coolant in a liquid phase may transform to a gaseous phase after absorption of heat at a cold plate 24. The coolant may transform back to the liquid phase after transferring the absorbed heat to another medium at the heat exchanger. Although not illustrated in FIG. 3, some embodiments of liquid cooling system 22 may also include valves or other known fluid control devices (not shown) to control the flow of the coolant therethrough. Further, although a closed-loop liquid cooling system 22 is described above, it is also contemplated that in some embodiments, the liquid cooling system 22 may be an open loop system instead of a closed loop system. In such an embodiment, the heated coolant from cold plate 24 may be replaced with cooler coolant from outside the cooling system.

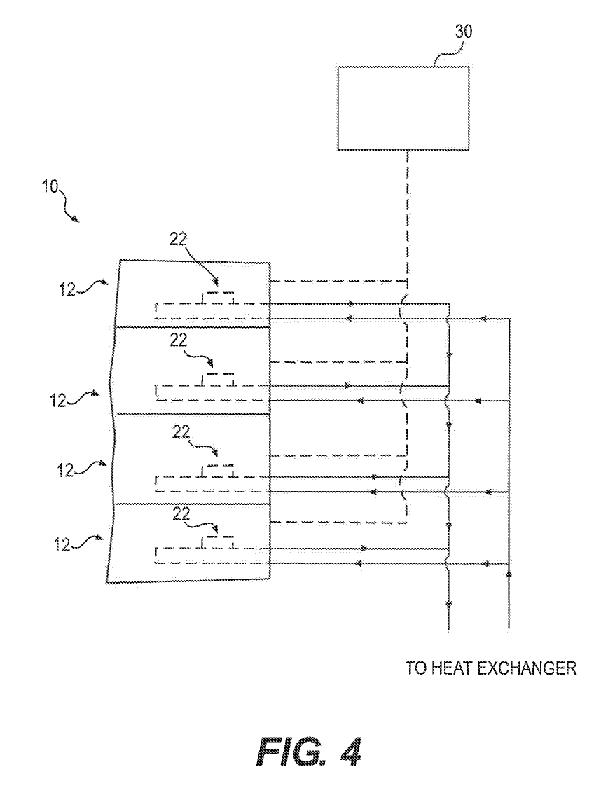

Multiple nodes 12 of server 10 may include liquid cooling systems. The liquid cooling systems of the multiple nodes may be similar to, or different from, liquid cooling system 22. FIG. 4 is a schematic illustration of a sever 10 with multiple nodes 12 each cooled by a liquid cooling system 22. In some embodiments, the heated coolant from each liquid cooling system 22 of the server 10 may be directed a heat exchanger located outside the server 10 to cool the coolant. In other embodiments, one or more heat exchangers may be located in the server 10, and the coolant of each liquid cooling system 22 may transfer heat to a second coolant (liquid or gas) at these heat exchangers. The second coolant may then be circulated to a heat exchanger located remote from the server 10 to be cooled. The flow of coolant in the liquid cooling system 22 of a node 12 may be controlled by the control circuits incorporated in the cold plates 24 of the liquid cooling system 22. The liquid cooling systems 22 of the multiple nodes 12 of a server 10 may also be electrically coupled to, and controlled by, a central control system 30. In some embodiments, the liquid cooling systems 22 of all the servers 10 in a server room (see FIG. 1) may be controlled by the central control system 30. Based on performance and other requirements, the central control system 30 may control the operation of the liquid cooling systems 22. As known in the art, control system 30 may include electronic and/or mechanical components that automatically control the operations of the liquid cooling system, and in some cases, the server 10.

Although proper design of a liquid cooling system 22 may minimize the possibility of a coolant leak in a node 12, it may be impractical to eliminate this possibility entirely. Coolant leak in a node 12 may affect the functioning of, or even damage, node 12. Therefore, liquid cooling system 22 may include a leak detection system adapted to detect a coolant leak, and indicate the node 12 in which the leak is occurring. Based in this indication, the central control system 30 (or in some embodiments, an operator) may shut off the coolant supply to selected nodes 12 and/or take other remedial measures.

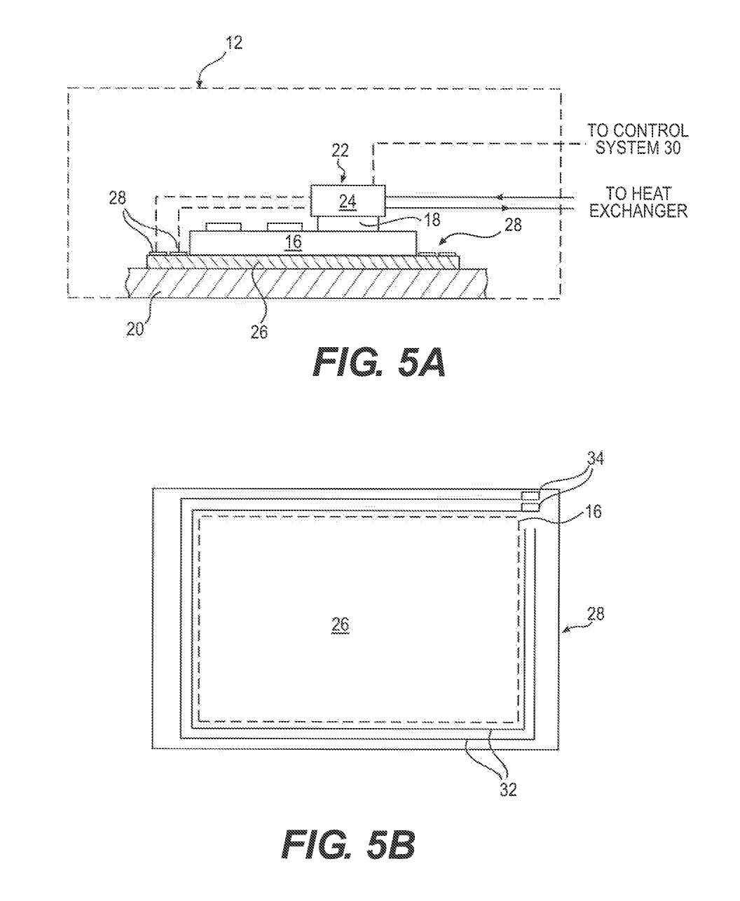

The leak detection system may comprise a leak detector associated with a node 12. In some embodiments, the leak detector may take the form of a substrate 26 having a leak detection circuit formed thereon. The leak detection circuit may be adapted to detect coolant leak. FIG. 5A is schematic cross-sectional illustration of an exemplary liquid cooling system including a substrate based leak detection system. In some embodiments, the substrate 26 may be a flexible film (flex circuit, flex PCB, tape, etc.) with the leak detection circuit formed thereon by conventional plating/deposition techniques. In some embodiments, the substrate 26 may be positioned proximate a surface of the motherboard 16 opposite the surface on which the cold plate(s) 24 of the liquid cooling system 22 is attached. The substrate 26 may be attached to the surface of the motherboard 16, or to a surface of the chassis 20. The substrate 26 may be attached to the motherboard 16 or the chassis 20 using an adhesive or another attachment material. The leak detection circuit 28 incorporated in substrate 26 may undergo a change in a measurable characteristic (such as, for example, resistance) when in contact with the coolant of liquid cooling system 22. The leak detection circuit 28 of substrate 26 may be electrically connected to central control system 30 to detect the presence of a leak.

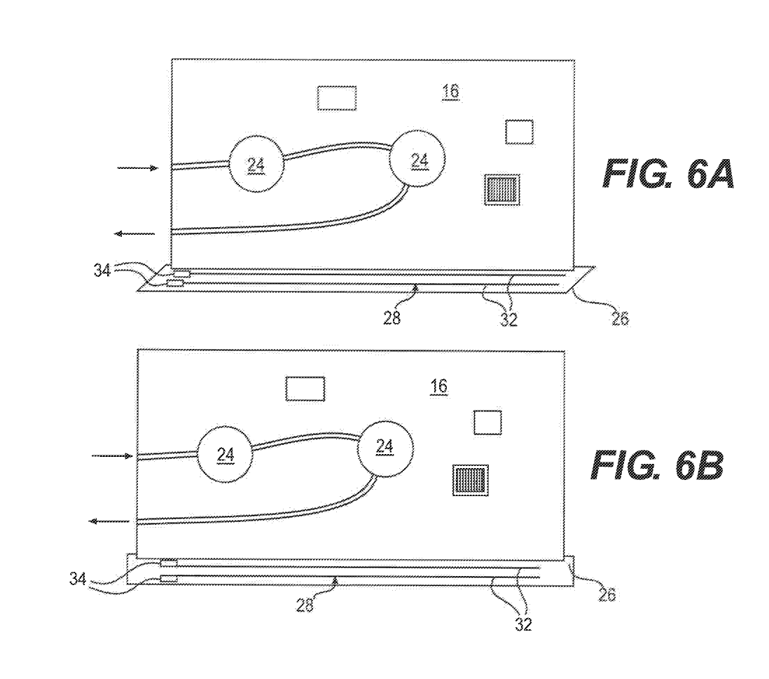

FIG. 5B is top view of substrate 26 showing an exemplary leak detection circuit 28. The perimeter of the motherboard 16 is shown in shadow in FIG. 6 to illustrate the relative positions of the leak detection circuit 28 and the motherboard 16. Leak detection circuit 28 may include spaced apart conductive traces 32 that extend along an outer region of the substrate 26. The conductive traces 32 may be formed of any electrically conductive material (such as, for example, copper, aluminum, etc.). When the motherboard 16 is positioned on the substrate 26, the conductive traces 32 extend along the perimeter of the motherboard 16. The relative positioning of the substrate 26 and the motherboard 16 is such that, if a coolant leak occurs, the leaked coolant will flow on the front surface of the motherboard 16, and drip (under the force of gravity) on the conductive traces 32. Terminals 34, formed at an end of the conductive traces 32, may be used to electrically couple the conductive traces 32 to the central control system 30. Since the conductive traces 32 are spaced apart, measurement of current between the terminals 34 will typically indicate an open circuit. However, if coolant drips on and shorts the conductive traces 32, measurement of current between the terminals 34 will indicate a closed circuit. In general, the resistance between the terminals may be an indicator of the amount of leaked coolant. Although FIG. 5B illustrates two parallel conductive traces 32 circumscribing the perimeter of the motherboard 16, this is only exemplary. In general, the conductive traces 32 may be patterned and positioned in any manner to enable the dripping of coolant thereon. For instance, in some embodiments, one of the conductive traces 32 may be covered by the edge of the motherboard 16 and the other conductive trace 32 may be immediately outside the edge of the motherboard 16.

Although FIG. 5B illustrates the substrate 26 as being positioned on the back side of the motherboard 16, this is only exemplary. In general, the relative orientation of the motherboard 16 and the substrate 26 will be such that the leaked coolant will flow under the three of gravity on the leak detection circuit 28. For instance, as illustrated in FIGS. 6A and 6B, in an embodiment of a server in which the motherboard 16 is oriented vertically, the substrate 26 may be positioned along a side edge of the motherboard 16 with its leak detection circuit 28 oriented to receive the leaked coolant thereon.

In some embodiments, the leak detection circuit 28 may be incorporated on, or attached to, the front side of the motherboard 16. In some such embodiments, the leak detection circuit 28 may include spaced apart conductive traces 32 (or other suitable structures) patterned and formed on the motherboard 16. In some embodiments, the conductive traces 32 may be formed on a film (similar to substrate 26), and the film attached to desired regions on the front side of the motherboard 16. These conductive traces 32 may generally be provided in regions of the motherboard 16 that are most likely to experience coolant leak, and oriented such that the leaked coolant flows under the force of gravity on to the conductive traces 32. For example, conductive traces 32 may be provided in a region of the motherboard 16 proximate cold plates 24, and/or in regions of the motherboard proximate separable fluid couplings of the liquid cooling system 22. The conductive traces 32 of the leak detection circuit 28 may then be electrically coupled to the central control system 30 to detect the presence of the leaked coolant.

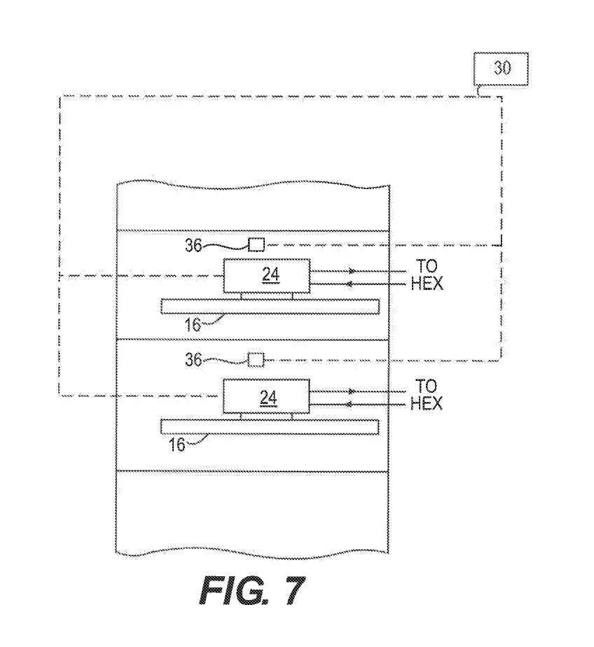

In some embodiments, as illustrated in FIG. 7, the leak detector of leak detection system may include a smell sensor 36 (electronic nose, electro chemical sensor, etc.) associated with a node 12, and adapted to sense the smell associated with an ingredient/additive of the coolant used in the liquid coolant system 22. The smell sensors 26 may be electrically coupled to the central control system 30 to detect the presence of the leaked coolant in a node 12. In some embodiments, a sensor that detects another characteristic of the coolant (for example, color, etc.) may be used as the leak detector.

When coolant leak is detected in a node 12 of the server 10, the control system 30 may take remedial action. The remedial action may include selectively turning off the coolant supply to the node 12 and/or alerting an operator (by activating an alarm, indicator light, etc.) of the leak. In some embodiments, upon detection of a leak, the control system 30 may additionally or alternatively selectively deactivate the node 12 in which the leak occurred to prevent damage to the node 12.

Although the leak detection systems above are described as being electrically connected to the central control system 30 of the server room, this is not a requirement. In some embodiments, the leak detector of a liquid cooling system 22 may be electrically connected to a control system of the liquid cooling system 22 (for example, the control circuits integrated with the cold plate 24). In such embodiments, the liquid cooling system 22 may turn itself off, or take other remedial actions when a leak is detected. It is also contemplated that, in some embodiments, the liquid cooling systems 22 (with its associated pumps, fans, etc.) and/or the leak detection systems (leak detection circuit 28, sensor 36, etc.) may be coupled to the control system 30 (or another control circuit) wirelessly.

It will be apparent to those skilled in the art that various modifications and variations can be made to the disclosed liquid cooling system with a leak detection system. Other embodiments will be apparent to those skilled in the art from consideration of the specification and practice of the disclosed cooling systems. It is intended that the specification and examples be considered as exemplary only, with a true scope being indicated by the following claims and their equivalents.

What is claimed is:

1. A liquid cooling system for a computer, comprising:
a cold plate configured to be positioned on a heat generating electronic device of the computer, the cold plate being adapted to pass a coolant therethrough;
a leak detection system configured to detect a coolant leak in the computer; and
a control system coupled to the leak detection system and configured to take remedial action when the coolant leak is detected by the leak detection system.

2. The liquid cooling system of claim 1, wherein the leak detection system includes a leak detection circuit positioned to receive leaked coolant thereon by a force of gravity.

3. The liquid cooling system of claim 1, wherein the leak detection system includes spaced apart electrical conductors configured to indicate an open circuit in an absence of coolant leak and a short circuit in a presence of coolant leak.

4. The liquid cooling system of claim 1, wherein the leak detection system includes a substrate with a leak detection circuit formed thereon.

5. The liquid cooling system of claim 4, wherein the heat generating electronic device is positioned on a front surface of a motherboard of the computer, and the substrate is positioned on a back surface of the motherboard.

6. The liquid cooling system of claim 4, where the substrate is a flexible film.

7. The liquid cooling system of claim 4, wherein the heat generating electronic device is positioned on a front surface of a motherboard of the computer, and the substrate is positioned along a side surface of the mother board.

8. The liquid cooling system of claim 1, wherein the leak detection system includes a sensor adapted to detect a smell associated with an ingredient of the coolant.

9. The liquid cooling system of claim 1, wherein the control system is configured to turn off the coolant supply to the cold plate when the coolant leak is detected.

10. A liquid cooling system for a computer server including multiple nodes arranged on a rack, comprising:
a first liquid loop configured to pass a coolant through a first node of the multiple nodes, and a second liquid loop configured to pass the coolant through a second node of the multiple nodes;
a leak detection system configured to detect a coolant leak in the server; and
a control system operatively coupled to the leak detection system and the first and second liquid loop, the control system being configured to identify a node of the server in which the coolant leak occurred.

11. The liquid cooling system of claim 10, wherein the first liquid loop is configured to cool one or more electronic devices of the first node, and the second liquid loop is configured to cool one or more electronic devices of the second node.

12. The liquid cooling system of claim 10, wherein the leak detection system includes a first leak detection circuit positioned in the first node and a second leak detection circuit positioned in the second node.

13. The liquid cooling system of claim 12, wherein at least one of the first leak detection circuit or the second leak detection circuit includes spaced apart electrical conductors configured to indicate an open circuit in an absence of coolant leak and a short circuit in a presence of coolant leak.

14. The liquid cooling system of claim 13, wherein the spaced apart electrical conductors are positioned to receive leaked coolant thereon by a force of gravity.

15. The liquid cooling system of claim 10, wherein the leak detection system includes a sensor adapted to detect a smell associated with an ingredient of the coolant.

16. The liquid cooling system of claim 10, wherein the control system is configured to selectively turn off coolant supply to the node of the server in which coolant leak occurred.

17. A liquid cooling system for a server room, the server room including multiple computer servers with each computer server including multiple nodes arranged on a rack, comprising:
a liquid loop configured to pass a coolant through a plurality of nodes of the multiple computer servers to cool one or more electronic devices positioned in the plurality of nodes;
a leak detection system configured to detect a coolant leak in the plurality of nodes; and
a control system operatively coupled to the leak detection system and the liquid loop, the control system being configured to identify a node of the plurality of nodes in which the coolant leak occurred.

18. The liquid cooling system of claim 17, wherein the plurality of nodes includes a first node of a first computer server and a second node of a second computer server.

19. The liquid cooling system of claim 17, wherein the lead detection system includes spaced apart electrical conductors positioned to receive leaked coolant thereon by a force of gravity.

20. The liquid cooling system of claim 17, wherein the leak detection system includes a sensor adapted to detect a smell associated with an ingredient of the coolant.
